(19) United States
(12) Patent Application Publication
(10) Pub. No.: US 2003/0001268 A1
(43) Pub. Date: Jan. 2, 2003

(54) Semiconductor device including cylinder-type capacitor and a manufacturing method thereof

(75) Inventor: Yong-chul Oh, Suwon-city (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 10/041,349

(22) Filed: Jan. 8, 2002

(30) Foreign Application Priority Data
Jun. 30, 2001 (KR) 2001-38813

(51) Int. Cl. H01L 21/8238

(52) U.S. Cl. 257/758

(57) ABSTRACT

A semiconductor device including a cylinder-type capacitor and a manufacturing method thereof are provided. The semiconductor device includes dielectric layer patterns formed on a semiconductor substrate. The dielectric layer patterns extend to the same height in a cell region and a peripheral circuit region of the semiconductor substrate and define a hole in the cell region. A lower electrode of a cylinder-type capacitor is formed to contact the bottom of the hole with a predetermined gap between the outer wall of the lower electrode and the sidewall of the hole. A dielectric layer is formed on the dielectric layer patterns and the lower electrode on the cell region. An upper electrode is formed on the dielectric layer. According to the semiconductor device and the manufacturing method thereof, a cylinder-type capacitor is formed in the cell region without generating a step difference between the cell region and the peripheral circuit region. Accordingly, it is possible to planarize an inter-metal dielectric layer introduced for performing a subsequent metal wiring process more easily than in the prior art. It is also possible to omit the process of planarizing the MD layer. In addition, since the dielectric layer patterns exist between adjacent lower electrodes, a bridge caused by contact between the adjacent lower electrodes is prevented.

### BACKGROUND OF THE INVENTION

1. Field of the Invention

The present invention relates to a semiconductor device and a manufacturing method thereof, and more particularly, to a semiconductor device including a cylinder-type capacitor and a manufacturing method thereof.

2. Description of the Related Art

The characteristics of a memory cell such as a dynamic random access memory (DRAM) are closely related to the capacitance of a cell capacitor. For example, as the capacitance of a cell capacitor increases, the low voltage characteristics and soft error characteristics of a memory cell improve. However, as the integration density of semiconductor devices increases, area occupied by a unit cell at which a capacitor will be formed continues to decrease. Accordingly, various methods for forming a capacitor to have an increased capacitance in a limited area have been proposed. For example, a method for increasing the effective area of an electrode by forming a lower electrode of a cylinder-type capacitor with the use of a sacrificial oxide layer have been suggested.

A conventional semiconductor device including a cylinder-type capacitor and a method for manufacturing the same will be described with reference to FIGS. 1 through 3. Referring to FIG. 1, a semiconductor substrate 10, on which a cell region C and a peripheral circuit region P are defined, is prepared. A contact pad 30 is formed to be self-aligned to two adjacent gates 20 in the cell region C. Next, a contact plug 45 is formed to contact the top surface of the contact pad 30. Reference numerals 25 and 35 represent interlayer dielectric layers.

Referring to FIG. 1, a sacrificial layer 50 is formed to include a storage node hole H, which exposes the top surface of the contact plug 45, on the contact plug 45 and the interlayer dielectric layer 35. Next, a conductive layer 55 is formed to a predetermined thickness on the sacrificial oxide layer 50. The storage node hole H is not completely filled with the conductive layer 55.

Referring to FIG. 2, predetermined portions of the conductive layer 55 formed on the sacrificial oxide layer 50 and the sacrificial oxide layer 50 are completely removed, thereby isolating storage nodes from one another. For example, an oxide layer (not shown) is formed on the conductive layer 55 so as to completely fill the storage node hole H, and then the top surface of the oxide layer is planarized, exposing the top surface of the sacrificial oxide layer 50. Next, the oxide layer remaining in the storage node hole H and the sacrificial oxide layer 50 are removed by wet etching, thus forming lower electrodes 55a that are isolated from one another.

Referring to FIG. 3, a dielectric layer 60 and an upper electrode 65 are sequentially formed on the lower electrodes 55a and then are patterned, thereby forming capacitors 70.

However, according to the conventional method for manufacturing a semiconductor device, a severe step difference may be generated between the cell region C and the peripheral circuit region P. This is because the sacrificial oxide layer 50 is completely removed in the step of isolating storage nodes from one another. Accordingly, in order to perform a subsequent metal wiring process, an inter-metal dielectric (IMD) layer must be formed on the semiconductor substrate 10 on which the capacitors 70 have been formed and then must be planarized.

There are two different methods for planarizing the IMD layer. In a first method, in order to planarize the IMD layer, a boron phosphorus silicate glass (BPSG) layer is formed as an IMD layer and then is reflowed. However, since reflowing process is performed at a high temperature, the characteristics of a transistor of a highly-integrated device may deteriorate, and the resistance of a contact region may increase due to the high temperature. Finally, the reliability of a semiconductor device may be lowered.

According to a second method, in order to planarize the IMD layer, an IMD layer is thickly formed on the entire surface of the semiconductor substrate 10 so that the top surface of a portion of the IMD layer formed in the peripheral circuit region P is higher than the top surfaces of the capacitors 70 formed in the cell region C. Next, a photoresist layer pattern is formed to expose only the cell region C. Predetermined portions of the IMD layer formed in the cell region C are etched using the photoresist layer pattern as an etching mask so that the step difference between the cell region and the peripheral circuit region P can be decreased. The photoresist layer pattern is removed, and the IMD layer is chemically and mechanically polished. However, this method is very complicated.

In the meantime, as the integration density of semiconductor devices increases, the thicknesses of layers constituting semiconductor devices decrease. Accordingly, the lower electrodes 55a may be bent during the step of isolating storage nodes from one another, which has been described above with reference to FIG. 2. Since the sacrificial oxide layer 50 is completely removed in the prior art, a lower electrode 55a may be bent such that it contacts an adjacent lower electrode, thus causing a bridge.

### SUMMARY OF THE INVENTION

To solve the above-described problems, it is a first object of the present invention to provide a semiconductor device that is capable of preventing a bridge caused by contact between adjacent lower electrodes of cylinder-type capacitors.

It is a second object of the present invention to provide a method for manufacturing a cylinder-type capacitor in a cell region without generating a step difference between the cell region and a peripheral circuit region.

The present invention is directed to a semiconductor device and a method of manufacturing a semiconductor device which overcome the drawbacks of the prior art.

In accordance with a first aspect of the invention, the semiconductor device includes dielectric layer patterns formed on a semiconductor substrate. Here, the dielectric layer patterns extend to the same height in a cell region and a peripheral circuit region of the semiconductor substrate and define a hole in the cell region. A lower electrode of a cylinder-type capacitor is formed to contact the bottom of the hole with a predetermined gap between the outer wall of the lower electrode and the sidewall of the hole. A dielectric layer is formed on the dielectric layer patterns and the lower electrode on the cell region. An upper electrode is formed on the dielectric layer.

In accordance with a second aspect, the semiconductor device includes dielectric layer patterns formed on a semiconductor substrate. Here, the dielectric layer patterns extend to the same height in a cell region and a peripheral circuit region of the semiconductor substrate and define a hole in the cell region. A conductive dummy pattern is formed at the bottom of the hole. A lower electrode of a cylinder-type capacitor is formed to contact the top surface of the conductive dummy pattern with a predetermined gap between the outer wall of the lower electrode and the sidewall of the hole. A dielectric layer is formed on the dielectric layer patterns and the lower electrode on the cell region. An upper electrode is formed on the dielectric layer.

In one embodiment, the conductive dummy pattern is a Ti layer, a TiN layer, or a composite layer consisting of a Ti layer and a TiN layer. The thickness of the conductive dummy pattern is preferably 150-250 Å.

In the semiconductor devices according to the first and second aspects of the present invention, the hole may expose the top surface of a contact plug electrically connected to a source/drain region. The predetermined gap between the outer wall of the lower electrode and the sidewall of the hole may be 150-250 Å. The upper and lower electrodes may be polysilicon layers. The dielectric layer may be an aluminum oxide (Al₂O₃) layer, a tantalum oxide (Ta₂O₅) layer, or a double layer including of a silicon nitride (Si₃N₄) layer and a silicon oxide (SiO₂) layer.

In accordance with a third aspect of the invention, there is provided a method for manufacturing a semiconductor device. According to the method, dielectric layer patterns are formed on a semiconductor substrate. Here, the dielectric layer patterns extend to the same height in a cell region and a peripheral circuit region of the semiconductor substrate and define a hole in the cell region. A lower electrode of a cylinder-type capacitor is formed to contact the bottom of the hole with a predetermined gap between the outer wall of the lower electrode and the sidewall of the hole. A dielectric layer is formed on the lower electrode but not completely filling the predetermined gap between the outer wall of the lower electrode and the sidewall of the hole. An upper electrode is formed on the dielectric layer, completely filling the predetermined gap between the outer wall of the lower electrode and the sidewall of the hole.

In one embodiment, tn order to form the lower electrode, a dummy pattern is formed to a predetermined thickness on the sidewall of the hole but not completely filling the hole. A conductive layer is formed to a predetermined thickness on the semiconductor substrate on which the dummy pattern is already formed but not completely filling the hole. A plurality of storage nodes isolated from one another are formed by removing the upper portion of the conductive layer, and the dummy pattern is removed. The thickness of the dummy pattern may be 150-250 Å. In a case where the dummy pattern is a silicon nitride layer, the dummy pattern is preferably removed by a wet etching process using phosphoric acid (H₂PO₄).

In accordance with a fourth aspect, the invention is directed to another method for manufacturing a semiconductor device. Dielectric layer patterns are formed on a semiconductor substrate. The dielectric layer patterns extend to the same height in a cell region and a peripheral circuit region of the semiconductor substrate and define a hole in the cell region. A conductive dummy pattern is formed at the bottom of the hole and then a lower electrode of a cylinder-type capacitor is formed to contact the conductive dummy pattern with a predetermined gap between the outer wall of the lower electrode and the sidewall of the hole. A dielectric layer is formed on the lower electrode but not completely filling the predetermined gap between the outer wall of the lower electrode and the sidewall of the hole. An upper electrode is formed on the dielectric layer, completely filling the predetermined gap between the outer wall of the lower electrode and the sidewall of the hole.

In one embodiment, in order to form the lower electrode, a conductive dummy layer is formed to a predetermined thickness on the semiconductor substrate on which the dielectric layer patterns are already formed, but not completely filling the hole. A conductive layer is formed to a predetermined thickness on the semiconductor substrate on which the conductive dummy layer is already formed but not completely filling the hole. A plurality of storage nodes isolated from one another are formed by removing the upper portion of the conductive layer and the upper portion of the conductive dummy layer. A conductive dummy pattern is formed by removing a predetermined portion of the conductive dummy layer formed at the sidewall of the hole.

The conductive dummy pattern may be a titanium (Ti) layer, a titanium nitride layer (TiN), or a composite layer consisting of a titanium (Ti) layer and a titanium nitride layer (TiN). The thickness of the conductive dummy layer may be 150-250 Å. In a case where the conductive dummy layer is a Ti layer, a TiN layer, or a composite layer consisting of a Ti layer and a TiN layer, the conductive dummy pattern is preferably formed by a wet etching process using ammonia (NH₃) and peroxide H₂O₂.

In the methods for manufacturing a semiconductor device according to the present invention, the predetermined gap between the outer wall of the lower electrode and the sidewall of the hole may be 150-250 Å. The conductive layer and the upper electrode may be formed of a polysilicon layer. The dielectric layer may be an aluminum oxide (Al₂O₃) layer, a tantalum oxide (Ta₂O₅) layer, or a double layer consisting of a silicon nitride (Si₃N₄) layer and a silicon oxide (SiO₂) layer.

According to the present invention, it is possible to manufacture a cylinder-type capacitor in a cell region without generating a step difference between the cell region and a peripheral circuit region. Accordingly, it is possible to planarize an inter-metal dielectric (IMD) layer introduced for performing a subsequent metal wiring process more easily than in the prior art. It is also possible to omit the process of planarizing the IMD layer. In addition, since there are dielectric layer patterns between adjacent lower electrodes, a bridge caused by contact between the adjacent lower electrodes can be prevented.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIGS. 1 through 3 are cross-sectional views illustrating a conventional semiconductor device including a cylinder-type capacitor and a manufacturing method thereof.

FIGS. 4 through 12 are cross-sectional views illustrating a semiconductor device including a cylinder-type capacitor and a manufacturing method thereof according to a first embodiment of the present invention.

FIGS. 13 through 19 are cross-sectional views illustrating a semiconductor device including a cylinder-type capacitor and a manufacturing method thereof according to a second embodiment of the present invention.

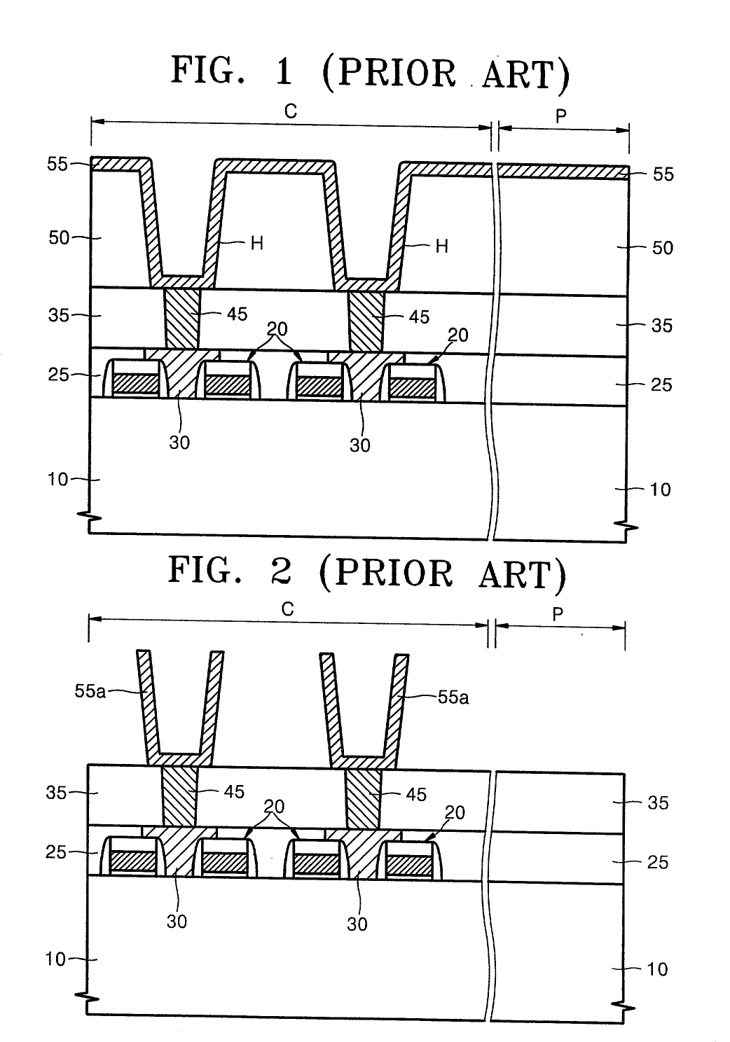

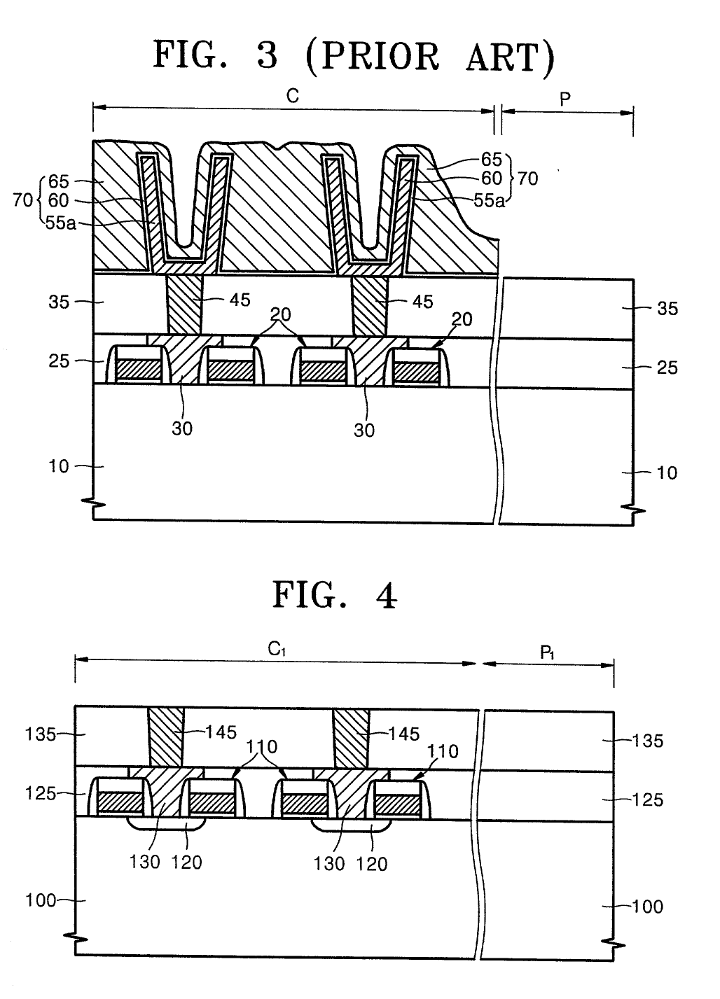

### DETAILED DESCRIPTION OF THE EMBODIMENTS

The present invention will now be described more fully with reference to the accompanying drawings, in which preferred embodiments of the invention are shown.

In the drawings, the thickness of layers and regions are exaggerated for clarity. It will also be understood that when a layer is referred to as being “on” another layer or substrate, it can be directly on the other layer or substrate, or intervening layers may also be present.

FIGS. 4 through 12 are cross-sectional views illustrating a semiconductor device including a cylinder-type capacitor and a manufacturing method thereof according to a first embodiment of the present invention. Referring to FIG. 12, the semiconductor device including a cylinder-type capacitor according to the first embodiment of the present invention includes dielectric layer patterns 150, which extend to the same height in a cell region C₁ and a peripheral circuit region P₁ formed on a semiconductor substrate 100. The dielectric layer patterns 150 define a hole H₁ in the cell region C₁. A lower electrode 170a of a cylinder-type capacitor is formed to contact the bottom of the hole H₁ with a predetermined gap between the outer wall of the lower electrode 170a and the sidewall of the hole H₁. A dielectric layer 175 is formed on the dielectric layer patterns 150 and the lower electrode 170a in the cell region C₁, and an upper electrode 180 is formed on the dielectric layer 175. In the present embodiment, there is little step difference between the cell region C₁ and the peripheral circuit region P₁. Accordingly, it is possible to planarize an inter-metal dielectric layer introduced for performing a subsequent metal wiring process more easily than in the prior art. It is also possible to omit the process of planarizing the IMD layer. In addition, since the dielectric layer patterns 150 exist, a bridge caused by contact between adjacent lower electrodes can be prevented.

Hereinafter, a method for manufacturing a semiconductor device including a cylinder-type capacitor according to the first embodiment of the present invention will be described more fully with reference to FIGS. 4 through 12. Referring to FIG. 4, the semiconductor substrate 100, on which the cell region C₁ and peripheral circuit region P₁ are defined, is provided. A contact pad 130 is formed to be self-aligned to two adjacent gates 110. Next, a contact plug 145 is formed to contact the top surface of the contact pad 130. The contact plug 145 is electrically connected to a source/drain region 120 in the cell region C₁ on the semiconductor substrate 100. Reference numerals 125 and 135 represent interlayer dielectric layers. The uppermost portion of the interlayer dielectric layer 135 is formed of a silicon nitride layer so that the interlayer dielectric layer 135 can act as an etching stopper in a subsequent process for forming 10 the dielectric layer patterns 150. If the interlayer dielectric layer 135 to be etched to form the contact plug 145 is thin, the contact plug 145 may be formed to directly contact the source/drain region 120 without forming the contact pad 130.

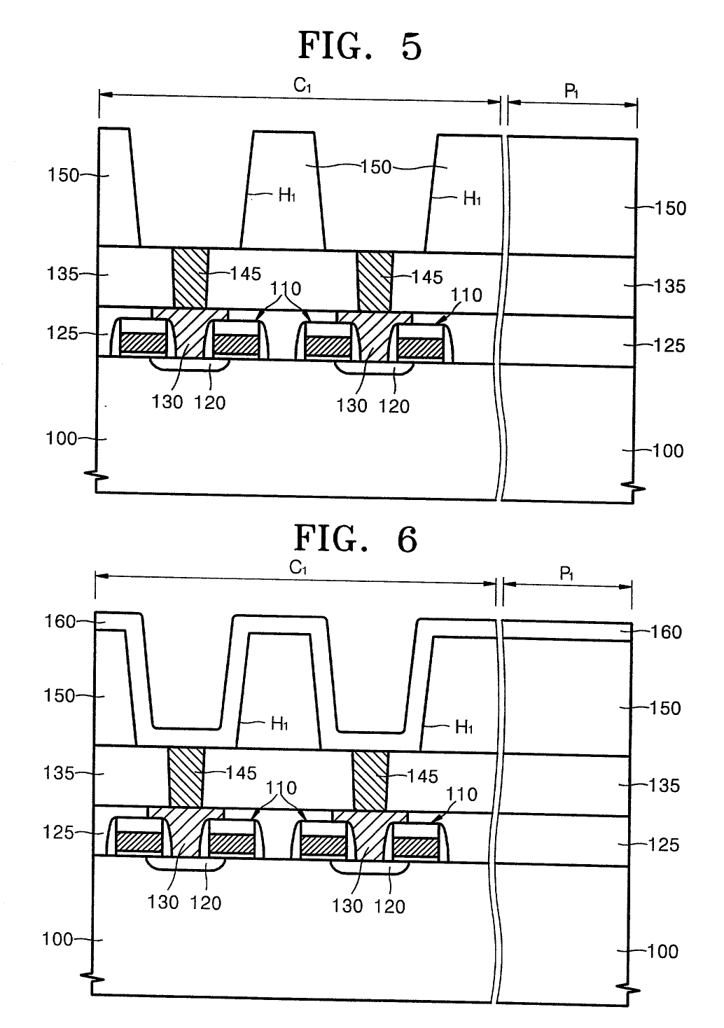

Referring to FIG. 5, dielectric layer patterns 150 are formed to extend to the same height in the cell region C₁ and peripheral circuit region P₁ of the semiconductor substrate 100. The dielectric layer patterns 150 define a hole H₁ exposing the top surface of the contact plug 145. For example, a silicon oxide layer is formed on the semiconductor substrate 100 shown in FIG. 4 by low pressure chemical vapor deposition (LPCVD). Next, the hole H₁ is formed exposing the top surface of the contact plug 145 by photolithography.

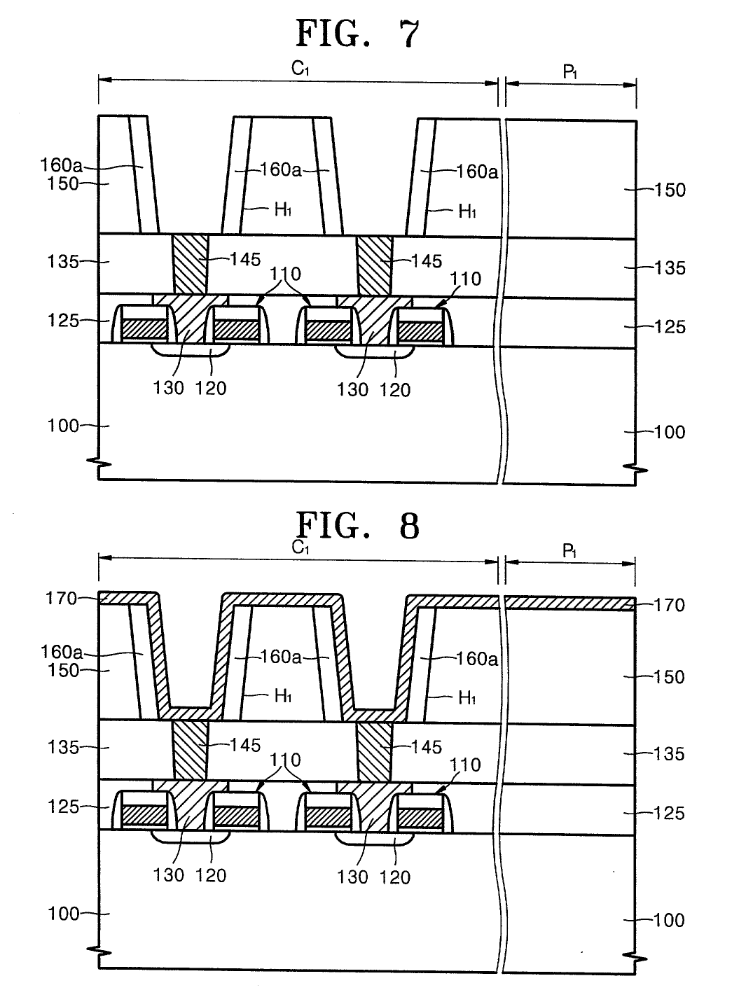

Referring to FIG. 6, a dummy layer 160 is formed on the semiconductor substrate 100 shown in FIG. 5. The hole H₁ is not completely filled with the dummy layer 160. The dummy layer 160 is preferably a silicon nitride layer. The silicon nitride layer may be formed by LPCVD.

Referring to FIG. 7, the dummy layer 160 is etched back until the top surfaces of the dielectric layer patterns 150 and the bottom of the hole H₁ are exposed. As a result, a dummy pattern 160a having a predetermined thickness is formed in the hole H₁ but not completely filling the hole H₁. The dummy pattern 160a is preferably formed to a thickness between 150 Å and 250 Å.

Referring to FIG. 8, a conductive layer 170 is formed to a predetermined thickness on the semiconductor substrate shown in FIG. 7. The hole H₁ is not completely filled with the conductive layer 170. The conductive layer 170 may be a polysilicon layer. The polysilicon layer may be formed by LPCVD. A step of doping the polysilicon layer may be performed in situ with the step of forming the polysilicon layer.

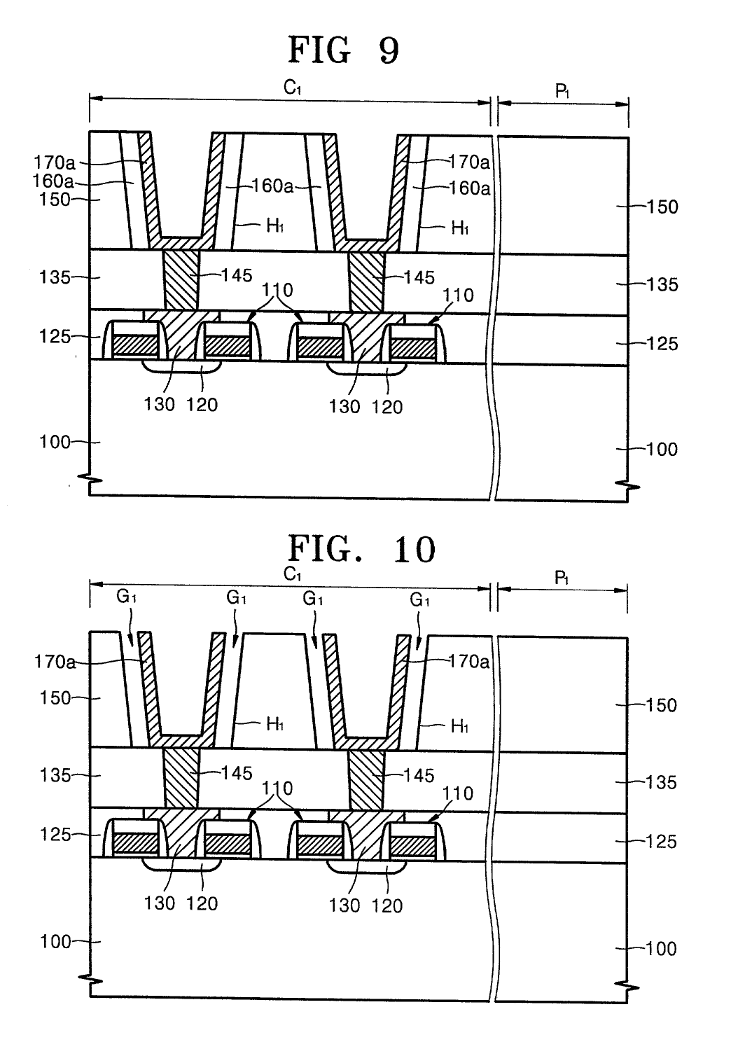

Referring to FIG. 9, the upper portion of the conductive layer 170 is removed, thereby forming a plurality of storage nodes 170a which are isolated from one another. For this, a photoresist layer (not shown) is deposited on the semiconductor substrate shown in FIG. 8, completely filling the hole H₁. The semiconductor substrate 100 on which the photoresist layer has been formed is planarized by chemical mechanical polishing (CMP) or etch-back until the top surfaces of the dielectric layer patterns 150 are exposed. Next, the photoresist layer remaining in the hole H₁ is removed. In the step of isolating the storage nodes 170a from one another, an oxide layer may be used instead of the photoresist layer.

Referring to FIG. 10, the dummy pattern 160a is removed from the semiconductor substrate shown in FIG. 9. At this time, it is preferable to use an etching process in which the dummy pattern 160a has an etching selectivity with respect to the dielectric layer patterns 150 and the conductive layer 170. Since the dummy pattern 160a is formed of a silicon nitride layer in the present embodiment, it is preferable to remove the dummy pattern 160a by wet etching using phosphoric acid. As a result of removing the dummy pattern 160a, the storage node 170a becomes a lower electrode of a cylinder-type capacitor which is in contact with the bottom of the hole H₁ with a gap G₁ formed between the sidewall of the hole H₁ and the outer wall of the storage node 170a. The width of the gap G₁ is the same as the thickness of the dummy pattern 160a. Since the dielectric layer patterns 150 exist between adjacent storage nodes 170a, a bridge caused by contact between the adjacent storage nodes 170a can be prevented.

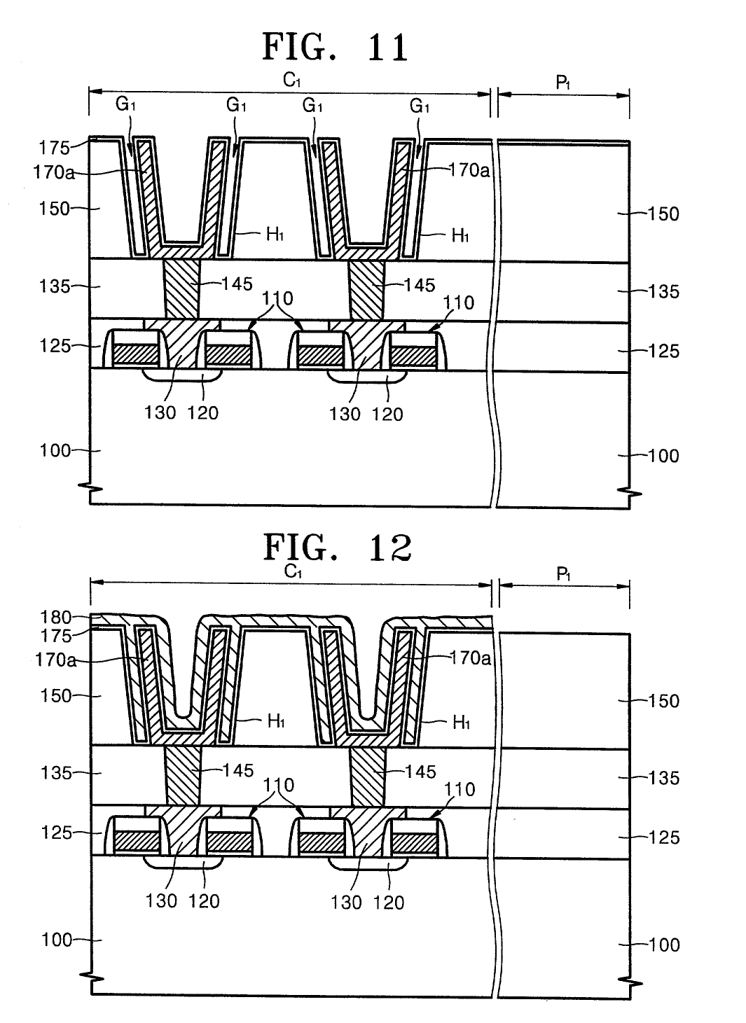

Referring to FIG. 11, a dielectric layer 175 is formed on the resulting structure to a predetermined thickness such that the gap G₁ is not completely filled with the dielectric layer 175. The dielectric layer 175 is formed on the top surfaces of the dielectric layer patterns 150, the sidewall and bottom of the hole H₁, and the surface of the storage node 170a. The dielectric layer 175 may be formed of an aluminium oxide layer, a tantalum oxide layer or a double layer including a silicon nitride layer and a silicon oxide layer.

Referring to FIG. 12, an upper electrode 180 is formed to completely fill the gap G₁ on the semiconductor substrate 100 shown in FIG. 11. The upper electrode 180 may be formed of a polysilicon layer. The polysilicon layer may be formed by LPCVD.

A step of doping the polysilicon layer may be performed in situ with the step of forming the polysilicon layer. The dielectric layer 175 and the upper electrode 180 are patterned, leaving the dielectric layer 175 and the upper electrode 180 in the cell region C₁.

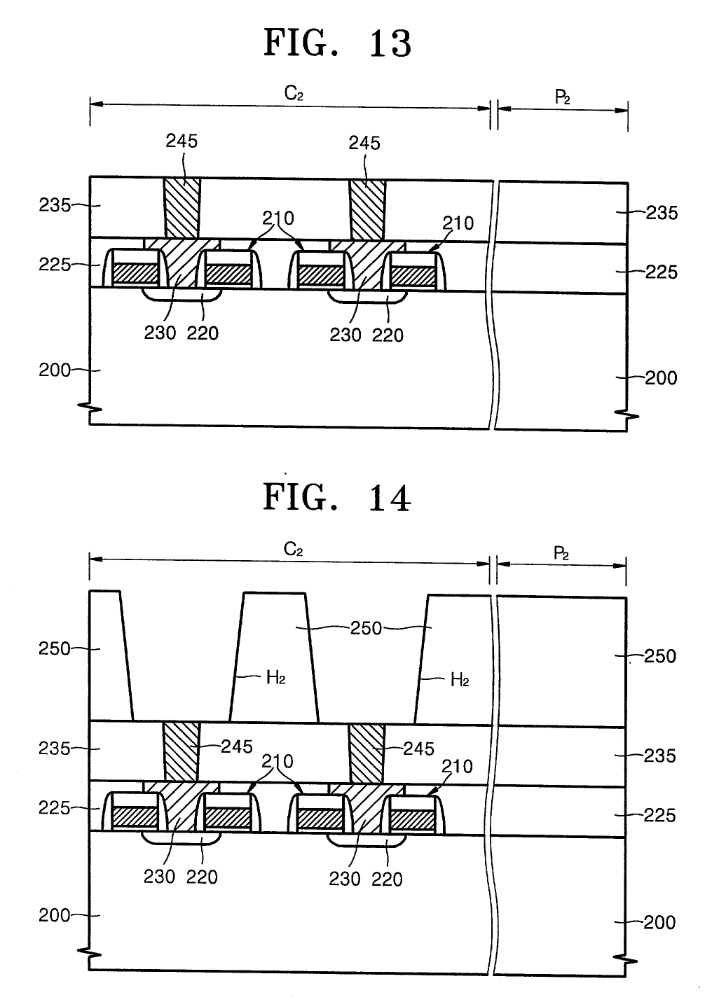

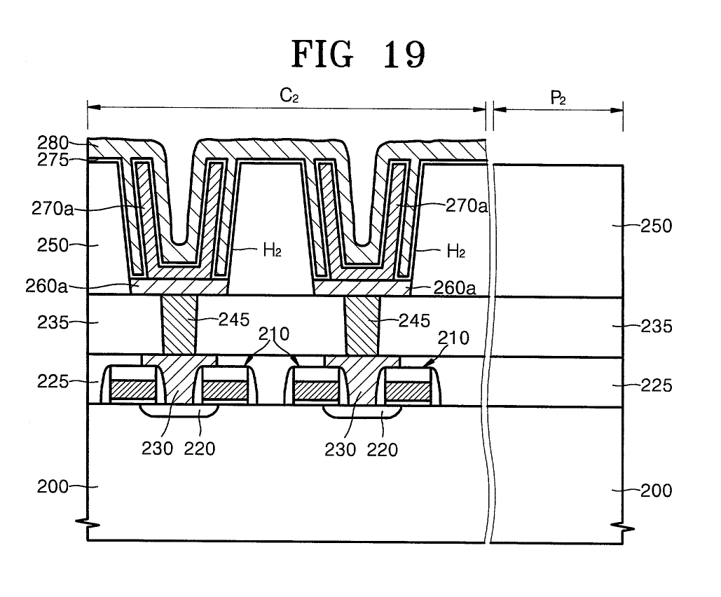

FIGS. 13 through 19 are cross-sectional views illustrating a semiconductor device including a cylinder-type capacitor and a manufacturing method thereof according to a second embodiment of the present invention. Referring to FIG. 19, the semiconductor device including a cylinder-type capacitor according to the second embodiment of the present invention includes dielectric layer patterns 250, which extend to the same height in a cell region C₂ and a peripheral circuit region P₂ formed on a semiconductor substrate 200. The dielectric layer patterns 250 define a hole H₂ in the cell region C₂. A lower electrode 270a of a cylinder-type capacitor is formed to contact the surface of a conductive dummy pattern 260a with a predetermined gap between the outer wall of the cylinder-type capacitor lower electrode 270a and the sidewall of the hole H₂. The dielectric layer 275 is formed on the dielectric layer patterns 250 and the lower electrode 270a in the cell region C₂, and an upper electrode 280 is formed on the dielectric layer 275. In the present invention, there is little step difference between the cell region C₂ and the peripheral circuit region P₂. Accordingly, it is possible to planarize an inter-metal dielectric layer introduced for performing a subsequent metal wiring process more easily than in the prior art. It is also possible to omit the process of planarizing the IMD layer. In addition, since the dielectric layer patterns 250 exist, a bridge caused by contact between adjacent lower electrodes can be prevented.

A method for manufacturing a semiconductor device including a cylinder-type capacitor according to the second embodiment of the present invention will be described more fully with reference to FIGS. 13 through 19. Referring to FIG. 13, the semiconductor substrate 200, on which the cell region C₂ and peripheral circuit region P₂ are defined, is provided. A contact plug 245 is formed to be electrically connected to a source/drain region 220 in the cell region C₂ on the semiconductor substrate 200. A contact pad 230 is formed to be self-aligned to two adjacent gates 210. Next, the contact plug is formed to contact the top surface of the contact pad 230. Reference numerals 225 and 235 represent interlayer dielectric layers. The uppermost portion of the interlayer dielectric layer 235 is formed of a silicon nitride layer so that the interlayer dielectric layer 235 can act as an etching stopper in a subsequent process for forming the dielectric layer patterns 250. If the interlayer dielectric layer 235 to be etched to form the contact plug 245 is thin, the contact plug 245 may be formed to directly contact the source/drain region 220 without forming the contact pad 230.

Referring to FIG. 14, dielectric layer patterns 250 are formed to extend to the same height in the cell region C₂ and peripheral circuit region P₂ of the semiconductor substrate 200. The dielectric layer patterns 250 define a hole H₂ exposing the top surface of the contact plug 245. For example, a silicon oxide layer is formed on the semiconductor substrate 200 shown in FIG. 13 by low pressure chemical vapor deposition (LPCVD). Next, the hole H₂ is formed, exposing the top surface of the contact plug 245 by photolithography.

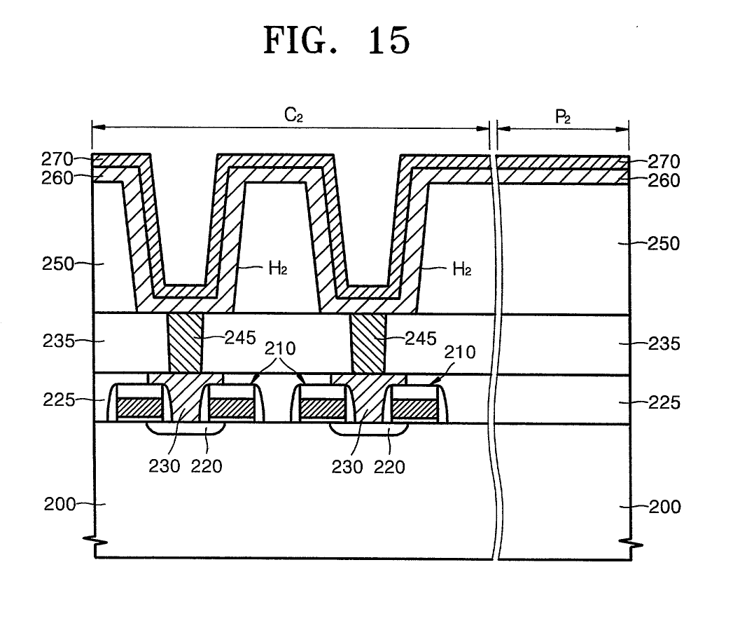

Referring to FIG. 15, a conductive dummy layer 260 is formed on the semiconductor substrate shown in FIG. 14 to a predetermined thickness. The hole H₂ is not completely filled with the conductive dummy layer 260. The conductive dummy layer 260 may be formed of a titanium layer, a titanium nitride layer, or a composite layer of a titanium layer and a titanium nitride layer. The conductive dummy layer 260 is preferably formed to a thickness of 150 Å to 250 Å. A conductive layer 270 is formed on the conductive dummy layer 260 but not completely filling the hole H₂. The conductive layer 270 may be a polysilicon layer. The polysilicon layer may be formed by LPCVD. A step of doping the polysilicon layer may be performed in situ with the step of forming the polysilicon layer.

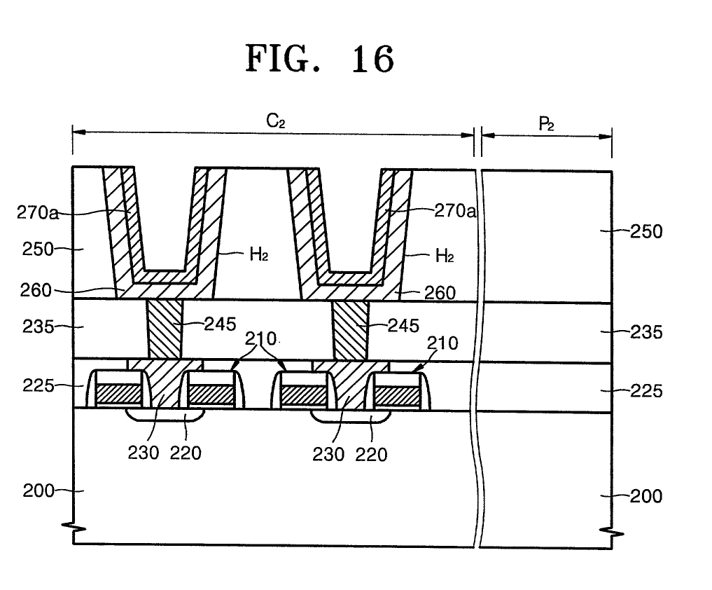

Referring to FIG. 16, the upper portions of the conductive layer 270 and the conductive dummy layer 260 are removed, thereby forming a plurality of storage nodes 270a which are isolated from one another. For this, a photoresist layer (not shown) is deposited on the semiconductor substrate shown in FIG. 15, filling the hole H₂ completely. The semiconductor substrate on which the photoresist layer has been formed is planarized by chemical mechanical polishing (CMP) or etch-back until the top surfaces of the dielectric layer patterns 250 are exposed. Next, the photoresist layer still remaining in the hole H₂ is removed. In the step of isolating the storage nodes 270a from one another, an oxide layer may be used instead of the photoresist layer.

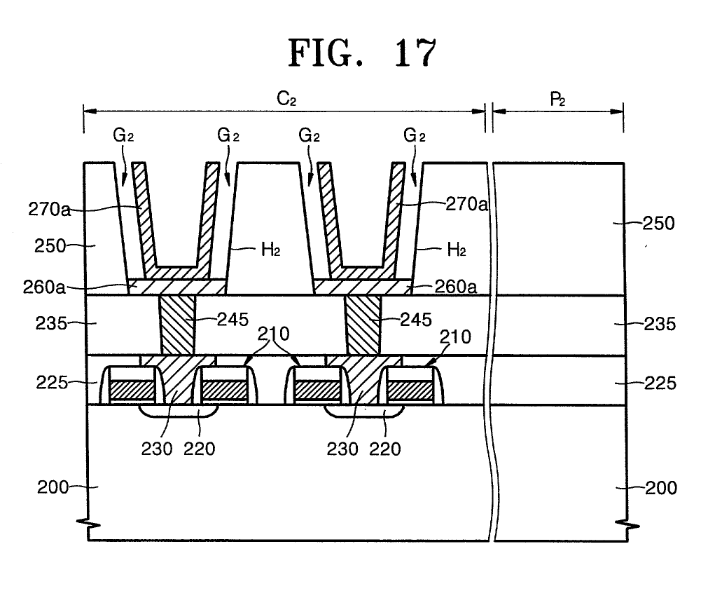

Referring to FIG. 17, predetermined portions of the conductive dummy layer 260 are removed such that the conductive dummy layer 260 remains only at the bottom of the hole H₂. As a result, a conductive dummy pattern 260a is formed. Preferably, an etching process in which the conductive dummy layer 260 has an etching selectivity with respect to the dielectric layer patterns 250 and the conductive layer 270 is used to partially remove the conductive dummy layer 260. Since the conductive dummy layer 260 is formed of a titanium layer, a titanium nitride layer or a composite layer of a titanium layer and a titanium nitride layer in the present embodiment, it is preferable to partially remove the conductive dummy layer 260 by wet etching using a solution containing ammonia and peroxide. The conductive dummy pattern 260 can be formed at the entire bottom of the hole H₂ by adjusting the etching time. As a result, the storage node 270a becomes a cylinder-type capacitor lower electrode contacting the conductive dummy pattern 260 with a gap G₂ formed between the outer wall of the storage node 270a and the sidewall of the hole H₂. The width of the gap G₂ is the same as the thickness of the conductive dummy layer 260. Since the dielectric layer patterns 250 exist between adjacent storage nodes 270a, a bridge caused by contact between the adjacent storage nodes 270a can be prevented.

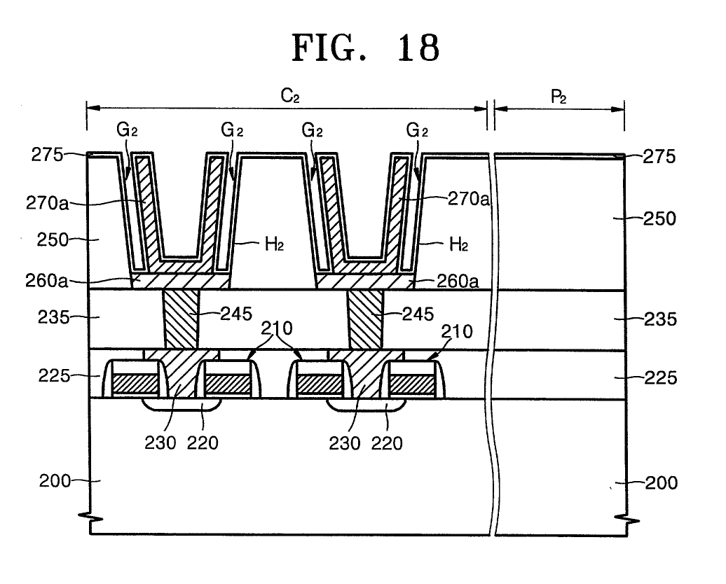

Referring to FIG. 18, a dielectric layer 275 is formed to a predetermined thickness such that the gap G₂ is not completely filled with the dielectric layer 275. The dielectric layer 275 is formed on the top surfaces of the dielectric layer patterns 150, the sidewall and bottom of the hole H₂, and the surface of the storage node 270a. The dielectric layer 275 may be formed of an aluminium oxide layer, a tantalum oxide layer or a double layer including a silicon nitride layer and a silicon oxide layer. Referring to FIG. 19, an upper electrode 280 is formed to completely fill the gap G₂ on the semiconductor substrate 200 shown in FIG. 18. The upper electrode 280 may be formed of a polysilicon layer. The polysilicon layer may be formed by LPCVD. A step of doping the polysilicon layer may be performed in situ with the step of forming the polysilicon layer. The dielectric layer 275 and the upper electrode 280 are patterned, leaving the dielectric layer 275 and the upper electrode 280 in the cell region C₂.

While this invention has been particularly shown and described with reference to preferred embodiments thereof, it will be understood by those skilled in the art that various changes in form and details may be made therein without departing from the spirit and scope of the invention as defined by the appended claims. For example, in the method for manufacturing a semiconductor device according to the embodiments of the present invention, the upper and lower electrodes of a capacitor are formed of a polysilicon layer. However, it is quite clear to those skilled in the art that the upper and lower electrodes of a capacitor may be formed of another conductive layer such as a metal layer.

According to the present invention, it is possible to manufacture a cylinder-type capacitor in a cell region without generating a step difference between the cell region and a peripheral circuit region. Accordingly, it is possible to planarize an inter-metal dielectric (IMD) layer introduced for performing a subsequent metal wiring process more easily than in the prior art. It is also possible to omit the process of planarizing the IMD layer. In addition, since there are dielectric layer patterns between adjacent lower electrodes, a bridge caused by contact between the adjacent lower electrodes can be prevented.

What is claimed is:

1. A semiconductor device comprising:
dielectric layer patterns formed on a semiconductor substrate, the dielectric layer patterns extending to the same height in a cell region and a peripheral circuit region of the semiconductor substrate and defining a hole in the cell region;
a lower electrode of a cylinder-type capacitor formed to contact the bottom of the hole with a predetermined gap between the outer wall of the lower electrode and the sidewall of the hole;
a dielectric layer formed on the dielectric layer patterns and the lower electrode on the cell region; and
an upper electrode formed on the dielectric layer.

2. The semiconductor device of claim 1, wherein the hole exposes the top surface of a contact plug electrically connected to a source/drain region.

3. The semiconductor device of claim 1, wherein the predetermined gap between the outer wall of the lower electrode and the sidewall of the hole is 150-250 Å.

4. The semiconductor device of claim 1, wherein the lower electrode is a polysilicon layer.

5. The semiconductor device of claim 1, wherein the dielectric layer is at least one of an aluminum oxide (Al₂O₃) layer, a tantalum oxide (Ta₂O₅) layer, and a double layer including a silicon nitride (Si₃N₄) layer and a silicon oxide (SiO₂) layer.

6. The semiconductor device of claim 1, wherein the upper electrode is a polysilicon layer.

7. A semiconductor device comprising:
dielectric layer patterns formed on a semiconductor substrate, the dielectric layer patterns extending to the same height in a cell region and a peripheral circuit region of the semiconductor substrate and defining a hole in the cell region;
a conductive dummy pattern formed at the bottom of the hole;
a lower electrode of a cylinder-type capacitor formed to contact the top surface of the conductive dummy pattern with a predetermined gap between the outer wall of the lower electrode and the sidewall of the hole;
a dielectric layer formed on the dielectric layer patterns and the lower electrode on the cell region; and
an upper electrode formed on the dielectric layer.

8. The semiconductor device of claim 7, wherein the hole exposes the top surface of a contact plug electrically connected to a source/drain region.

9. The semiconductor device of claim 7, wherein the thickness of the conductive dummy pattern is 150-250 Å.

10. The semiconductor device of claim 7, wherein the conductive dummy pattern is at least one of a titanium (Ti) layer, a titanium nitride layer (TiN), and a composite layer including a titanium (Ti) layer and a titanium nitride layer (TiN).

11. The semiconductor device of claim 7, wherein the predetermined gap between the outer wall of the lower electrode and the sidewall of the hole is 150-250 Å.

12. The semiconductor device of claim 7, wherein the lower electrode is a polysilicon layer.

13. The semiconductor device of claim 7, wherein the dielectric layer is at least one of an aluminum oxide (Al₂O₃) layer, a tantalum oxide (Ta₂O₅) layer, and a double layer including a silicon nitride (Si₃N₄) layer and a silicon oxide (SiO₂) layer.

14. The semiconductor device of claim 7, wherein the upper electrode is a polysilicon layer.

15. A method for manufacturing a semiconductor device comprising:
forming dielectric layer patterns on a semiconductor substrate, the dielectric layer patterns extending to the same height in a cell region and a peripheral circuit region of the semiconductor substrate and defining a hole in the cell region;
forming a lower electrode of a cylinder-type capacitor to contact the bottom of the hole with a predetermined gap between the outer wall of the lower electrode and the sidewall of the hole;
forming a dielectric layer on the lower electrode but not completely filling the predetermined gap between the outer wall of the lower electrode and the sidewall of the hole; and
forming an upper electrode on the dielectric layer, completely filling the predetermined gap between the outer wall of the lower electrode and the sidewall of the hole.

16. The method of claim 15, wherein the predetermined gap between the outer wall of the lower electrode and the sidewall of the hole is 150-250 Å.

17. The method of claim 15, wherein forming the lower electrode comprises:
forming a dummy pattern to a predetermined thickness on the sidewall of the hole but not completely filling the hole;
forming a conductive layer to a predetermined thickness on the semiconductor substrate on which the dummy pattern is already formed but not completely filling the hole;
forming a plurality of storage nodes isolated from one another by removing the upper portion of the conductive layer; and
removing the dummy pattern.

18. The method of claim 17, wherein forming the dummy pattern comprises:
forming a dummy layer to a predetermined thickness on the semiconductor substrate, on which the dielectric layer patterns are already formed, but not completely filling the hole; and
etching-back the dummy layer until the top surfaces of the dielectric layer patterns and the bottom of the hole are exposed.

19. The method of claim 18, wherein the dummy layer is a silicon nitride layer.

20. The method of claim 17, wherein the thickness of the dummy pattern is 150-250 Å.

21. The method of claim 17, wherein the conductive layer is a polysilicon layer.

22. The method of claim 17, wherein removing the dummy pattern is performed using an etching process in which the dummy pattern has an etching selectivity with respect to the dielectric layer patterns and the conductive layer.

23. The method of claim 22, wherein the dummy pattern is formed of a silicon nitride layer, and the etching process is a wet etching process using phosphoric acid (H₂PO₄).

24. The method of claim 15, wherein the dielectric layer is at least one of an aluminum oxide (Al₂O₃) layer, a tantalum oxide (Ta₂O₅) layer, and a double layer including a silicon nitride (Si₃N₄) layer and a silicon oxide (SiO₂) layer.

25. The method of claim 15, wherein the upper electrode is formed of a polysilicon layer.

26. A method for manufacturing a semiconductor device comprising:
forming dielectric layer patterns on a semiconductor substrate, the dielectric layer patterns extending to the same height in a cell region and a peripheral circuit region of the semiconductor substrate and defining a hole in the cell region;
forming a conductive dummy pattern at the bottom of the hole and then forming a lower electrode of a cylinder-type capacitor to contact the conductive dummy pattern with a predetermined gap between the outer wall of the lower electrode and the sidewall of the hole;
forming a dielectric layer on the lower electrode but not completely filling the predetermined gap between the outer wall of the lower electrode and the sidewall of the hole; and
forming an upper electrode on the dielectric layer, completely filling the predetermined gap between the outer wall of the lower electrode and the sidewall of the hole.

27. The method of claim 26, wherein the predetermined gap between the outer wall of the lower electrode and the sidewall of the hole is 150-250 Å.

28. The method of claim 26, wherein the conductive layer is a polysilicon layer.

29. The method of claim 26, wherein the step of forming the lower electrode comprises:
forming a conductive dummy layer to a predetermined thickness on the semiconductor substrate on which the dielectric layer patterns are already formed, but not completely filling the hole;
forming a conductive layer to a predetermined thickness on the semiconductor substrate on which the conductive dummy layer is already formed but not completely filling the hole;
forming a plurality of storage nodes isolated from one another by removing the upper portion of the conductive layer and the upper portion of the conductive dummy layer; and
forming a conductive dummy pattern by removing a predetermined portion of the conductive dummy layer formed at the sidewall of the hole.

30. The method of claim 29, wherein the conductive dummy pattern is at least one of a titanium (Ti) layer, a titanium nitride layer (TiN), and a composite layer including a titanium (Ti) layer and a titanium nitride layer (TiN).

31. The method of claim 29, wherein the thickness of the conductive dummy layer is 150-250 Å.

32. The method of claim 29, wherein forming the conductive dummy pattern is performed using an etching process in which the conductive dummy layer has an etching selectivity with respect to the dielectric layer patterns and the conductive layer.

33. The method of claim 32, wherein the conductive dummy layer is formed of at least one of a titanium (Ti) layer, a titanium nitride layer (TiN), and a composite layer including a titanium (Ti) layer and a titanium nitride layer (TiN), and the etching process is a wet etching process using ammonia (NH₃) and peroxide (H₂O₂).

34. The method of claim 26, wherein the dielectric layer is at least one of an aluminum oxide (Al₂O₃) layer, a tantalum oxide (Ta₂O₅) layer, and a double layer including a silicon nitride (Si₃N₄) layer and a silicon oxide (SiO₂) layer.

35. The method of claim 26, wherein the upper electrode is formed of a polysilicon layer.
